(19) United States
(12) Patent Application Publication
(10) Pub. No.: US 2013/0141150 A1
(43) Pub. Date: Jun. 6, 2013

(54) METHOD FOR GENERATING A MULTIPHASE PWM SIGNAL

(71) Applicants: Dieter Thoss, Schwieberdingen (DE); Stephen Schmitt, Nuertingen (DE)

(72) Inventors: Dieter Thoss, Schwieberdingen (DE); Stephen Schmitt, Nuertingen (DE)

(21) Appl. No.: 13/637,427

(22) PCT Filed: Mar. 17, 2011
(86) PCT No.: PCT/EP2011/054042

§ 371 Date: Dec. 26, 2012

(30) Foreign Application Priority Data
Mar. 31, 2010 (DE) 102010003513.0

(51) Int. Cl. H03K 3/017

(52) U.S. Cl. CPC H03K 3/017
USPC 327/176

(57) ABSTRACT

A method and a circuit configuration are provided for generating a multiphase PWM signal. For this purpose a number of PWM generators are provided, which respectively have one counter, two comparators and one state memory, each PWM generator outputting a PWM signal, which represents a phase of the multiphase PWM signal, the PWM generators being coupled with one another via multiplexers such that the counters of the PWM generators that are coupled with one another are clocked identically.

### BACKGROUND OF THE INVENTION

1. Field of the Invention

The present invention relates to a method for generating a multiphase PWM signal and to a circuit configuration for implementing the method.

2. Description of the Related Art

In pulse width modulation, a square-wave signal is generated that has a variable pulse width (duty cycle) and a variable frequency or period. The generation of pulse-width modulated signals (PWM signals) is a known objective. The generated signals are used for example in microcontrollers in the automotive sector. Since in a motor vehicle various components have to be controlled using different PWM signals, known microcontrollers contain more than 100 PWM generators.

To generate a multiphase PWM signal it seems necessary to couple multiple PWM signal generators to one another.

The requirements for multiphase PWM signal generators are increasing continually, for example when controlling a brushless DC motor. In this connection, multiphase PWM means that some PWM lines, which correspond to phases, share the same period with arbitrary build-up and decay times for each line and precisely defined phase ratios between the lines.

A known approach provides for generating various PWM signals by using counters and comparators that may be connected to one another. The disadvantage in this approach is that the desired flexibility requires a great number of multiplexers.

Another possibility is to provide for separate hardware for single-phase and multiphase signals respectively. However, this does not represent a solution of sufficiently high flexibility.

### BRIEF SUMMARY OF THE INVENTION

The method described and the circuit configuration presented allow for a flexible generation of multiphase PWM signals with little effort. It is merely necessary to add to each PWM generator one multiplexer, for example a 1 bit multiplexer.

It is understood that the features mentioned above and the features yet to be described below may be used not only in the combination given in each case but also in other combinations or individually, without departing from the scope of the present invention.

### BRIEF DESCRIPTION OF THE DRAWING

FIG. 1 shows a specific embodiment of the described circuit configuration in a block diagram.

### DETAILED DESCRIPTION OF THE INVENTION

The present invention is represented schematically in the drawing on the basis of a specific embodiment and is described in detail below with reference to the drawing.

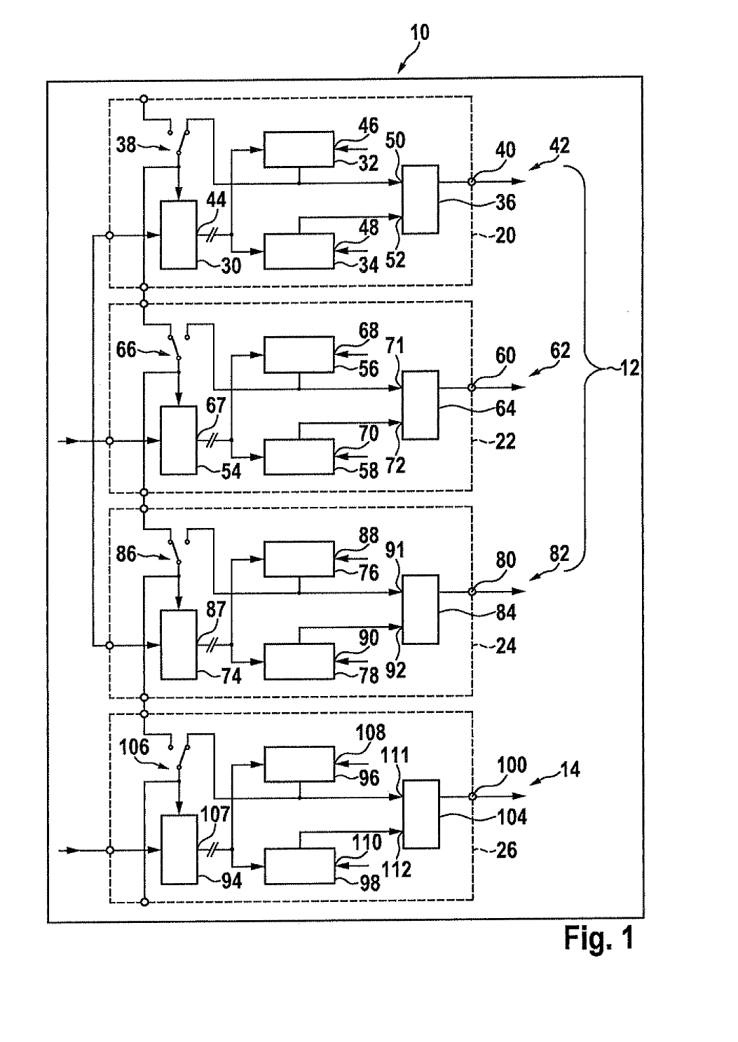

FIG. 1 shows a circuit configuration 10 representing four PWM generators that generate a multiphase signal, in this case a three-phase PWM signal 12 and a normal single-phase PWM signal 14.

In detail, circuit configuration 10 shows a first PWM generator 20, a second PWM generator 22, a third PWM generator 24 and a fourth PWM generator 26. On one output 40 of PWM generator 20, PWM signal 42 is output. On one output 60 of PWM generator 22, PWM signal 62 is output. On one output 80 of PWM generator 24, PWM signal 82 is output. On one output 100 of PWM generator 26, PWM signal 14 is output.

First PWM generator 20 has a counter 30, an upper comparator 32, a lower comparator 34, a state memory 36, in this case an RS flipflop, and a multiplexer 38, which in this case is developed as a 1 bit multiplexer or switch. On one output 40 of PWM generator 20, PWM signal 42 is output. On one output 44 of counter 30, an n bit signal is output. On one input 46 of upper comparator 32, the period of PWM signals 42, 62, 82 is applied. On one input 48 of lower comparator 34, the falling edge of PWM signal 42 is applied. State memory 36, which is developed as an RS flipflop, has a set input 50 and a reset input 52.

Second PWM generator 22 has a counter 54, an upper comparator 56, a lower comparator 58, a state memory 64, in this case an RS flipflop, and a multiplexer 66, which in this case is developed as a 1 bit multiplexer or switch. On one output 60 of PWM generator 22, PWM signal 62 is output. On one output 67 of counter 54, an n bit signal is output. On one input 68 of upper comparator 56, the rising edge of PWM signal 62 is applied. On one input 70 of lower comparator 58, the falling edge of PWM signal 62 is applied. State memory 64, which is developed as an RS flipflop, has a set input 71 and a reset input 72.

Third PWM generator 24 has a counter 74, an upper comparator 76, a lower comparator 78, a state memory 84, in this case an RS flipflop, and a multiplexer 86, which in this case is developed as a 1 bit multiplexer or switch. On output 80 of PWM generator 24, PWM signal 82 is output. On one output 87 of counter 74, an n bit signal is output. On one input 88 of upper comparator 76, the rising edge of PWM signal 82 is applied. On one input 90 of lower comparator 78, the falling edge of PWM signal 82 is applied. State memory 84, which is developed as an RS flipflop, has a set input 91 and a reset input 92.

Fourth PWM generator 26 has a counter 94, an upper comparator 96, a lower comparator 98, a state memory 104, in this case an RS flipflop, and a multiplexer 106, which in this case is developed as a 1 bit multiplexer or switch. On output 100 of PWM generator 26, PWM signal 14 is output. On one output 107 of counter 94, an n bit signal is output. On one input 108 of upper comparator 96, the period of PWM signal 14 is applied. On one input 110 of lower comparator 98, the duty cycle of PWM signal 14 is applied. State memory 104, which is developed as an RS flipflop, has a set input 111 and a reset input 112.

Each of the PWM generators 20, 22, 24 and 26 contains a counter 30, 54, 74 and 94, two comparators 32, 34; 56, 58; 76, 78 and 96, 98, a state memory 36, 64, 84, 104, in this case an RS flipflop. The shadow register and the additional synchronization logic circuit for the purpose of updating all phases uniformly are not shown in the figure for reasons of clarity.

In each of the PWM generators 20, 22, 24 and 26, counter 30, 54, 74 and 94, respectively, starts at zero. The output is assumed as a one. When counter 30, 54, 74 and 94 reaches the value of lower comparator 34, 58, 78 and 98, respectively, the output is set to zero. When counter 30, 54, 74 and 94 reaches the value of upper comparator 32, 56, 76 and 96, respectively, the output is set to one.

In the normal single-phase mode, upper comparator 96 resets counter 94 (right position of multiplexer 106), as shown in PWM generator 26. In order to generate multiphase PWM signal 12, multiplexer 38 in PWM generator A 20 of the first phase remains in the right position and multiplexers 66, 86 of all coupled subsequent phases, i.e. in PWM generator 22 and PWM generator 24, are switched to the left position.

Now counters 30, 54, 74 are respectively reset simultaneously. They share the same period, which is defined by upper comparator 32 in PWM generator 20. Upper comparators 56, 76 in 22 and 24 may be used to define an arbitrary rising edge for phases 62 and 82. Phase 42 always starts directly with a rising edge.

Lower comparators 34, 58, 78 in 20, 22, 24 define the falling edge individually for each phase. A special synchronization logic circuit ensures that all six comparators 32, 34, 56, 58, 76 and 78 are updated simultaneously when counters 30, 54, 74 are reset.

All PWM generators 20, 22, 24, which are coupled for a multiphase PWM signal generation, must share the same clock pulse for all counters 30, 54, 74. Any number of phases may be generated, for example six phases, in order to control a three-phase H bridge with arbitrary timeouts.

1-10. (canceled)

11. A method for generating at least a multiphase PWM signal, comprising:
providing multiple PWM generators which each have one counter, two comparators, and one state memory, wherein the PWM generators are coupled with one another via multiplexers such that the counters of the PWM generators are clocked identically; and
generating multiple PWM signals using the multiple PWM generators, wherein each PWM generator outputs a respective PWM signal which represents a phase of the multiphase PWM

12. The method as recited in claim 11, wherein all the comparators of the PWM generators are updated simultaneously when the counters are reset.

13. The method as recited in claim 12, wherein the reset of all the comparators is ensured by a synchronization logic circuit.

14. The method as recited in claim 12, wherein the multiphase PWM signal is generated to control an H bridge circuit with arbitrary timeouts.

15. The method as recited in claim 12, wherein a single-phase PWM signal is additionally generated.

16. A circuit configuration for generating a multiphase PWM signal, comprising:
multiple PWM generators which each contain one counter, two comparators, one state memory, and a multiplexer, wherein the multiple PWM generators are coupled with one another via the multiplexers.

17. The circuit configuration as recited in claim 16, wherein a flipflop is used as the state memory.

18. The circuit configuration as recited in claim 16, wherein the multiplexer is a 1-bit multiplexer.

19. The circuit configuration as recited in claim 18, wherein a switch is used as the 1-bit multiplexer.

20. The circuit configuration as recited in claim 18, further comprising:
a synchronization logic circuit.
